(19) United States
(12) Patent Application Publication
(10) Pub. No.: US 2022/0011636 A1
(43) Pub. Date: Jan. 13, 2022

(54) INORGANIC ALIGNMENT FILM FORMING APPARATUS FOR LCOS DISPLAY

(71) Applicant: VISIONAID INC., Pocheon-si, Gyeonggi-do (KR)

(72) Inventors: Kyo Wung LEE, Suwon-si (KR); Sung Il KIM, Pyeongtaek-si (KR); Man Bok PARK, Seongnam-si (KR)

(73) Assignee: VISIONAID INC., Pocheon-si, Gyeonggi-do (KR)

(21) Appl. No.: 17/289,937

(22) PCT Filed: Oct. 8, 2019
(86) PCT No.: PCT/KR2019/013169

§ 371 Date: Apr. 29, 2021

(30) Foreign Application Priority Data
Dec. 14, 2018 (KR) 10-2018-0161840

(51) Int. Cl. G02F 1/1337; H01L 21/02; H01L 21/265

(52) U.S. Cl. CPC G02F 1/133788; H01L 21/26566; H01L 21/02266

(57) ABSTRACT

The present invention relates to an inorganic alignment film forming apparatus for forming an inorganic alignment film on a substrate, the apparatus comprising: a sputtering means; and an ion beam irradiation means for performing surface treatment on an inorganic alignment film formed by the sputtering means, wherein the sputtering means comprises a stage on which a substrate for forming the inorganic alignment film is arranged, at least one sputtering gun, and a sputtering mask arranged between the stage and the sputtering gun, the ion beam irradiation means comprises a stage on which the substrate is arranged, an ion beam emission unit for generating ions and irradiating the substrate with ions, and an ion beam irradiation mask arranged between the stage and the ion beam emission unit, and the sputtering mask and the ion beam irradiation mask have a plurality of inclined opening parts.

### TECHNICAL FIELD

The present disclosure relates to an inorganic alignment film forming apparatus for an LCOS display, and more particularly, to an apparatus for forming an inorganic alignment film on the surface of a substrate used for an LCOS display using a sputtering means and an ion beam radiation means.

### BACKGROUND ART

Recently, the demand for a display having a large size, high resolution and small volume is increasing. Among these displays, a liquid crystal display (LCD) uses optically anisotropic liquid crystals to create an image and thus may be fabricated with a smaller thickness than a conventional cathode ray tube (CRT). LCDs have been widely used due to low power consumption thereof. However, recently, LCOS (Liquid Crystal On Silicon) displays with a high response speed and an excellent viewing angle have been developed to expand application fields.

The LCOS display, which is an active drive type display that operates in a reflection mode, is fabricated by replacing the glass substrate, which has been used as a lower plate in the conventional TFT-LCD, with a silicon substrate and forming a circuit on the substrate, thereby facilitating arrangement of individual components and enabling implementation of a compact design.

In the LCOS display, liquid crystals are injected into the gap between an upper glass substrate and a lower silicon substrate. To align the injected liquid crystals, alignment films are formed on the bottom surface of the glass substrate and the top surface of the silicon substrate. The pretilt angle of the liquid crystal molecules, that is, the initial tilt angle formed by the long axis of the liquid crystal molecules with respect to the surface of the substrate, varies. When the pretilt angle is not sufficiently large, the response speed of the LCOS display is slowed. In addition, when the pretilt angle is not uniformly formed over the entire display, the image quality on the display becomes uneven.

Conventionally, four-way evaporation has been used to form an inorganic alignment film for the LCOS display. Four-way evaporation is a technique of depositing inorganic substances such as metals, carbides, oxides, and impurities on a substrate by vaporizing the same using an electron beam in a vacuum atmosphere. According to this evaporation technique, the alignment of liquid crystal molecules depends on evaporation conditions such as an evaporation angle, an evaporation rate, a vacuum degree, a substrate temperature, and a film thickness, and the material or liquid crystal material used in the evaporation. An oxide film such as SiO₂ formed by the four-way evaporation may provide a high pretilt angle and has high-temperature stability superior to an organic alignment film such as a polyimide film. However, the four-way evaporation method provides an inclination to the substrate during the evaporation process. Accordingly, a part that is close to the evaporation source becomes thick when deposited, whereas a part that is positioned far from the source becomes thin when deposited. Thus, thickness uniformity of the deposited thin film is degraded. As a result, a uniform pretilt angle may not be obtained. Furthermore, it is difficult to apply the method to a large display.

### DISCLOSURE

### Technical Problem

Therefore, the present disclosure has been made in view of the above problems, and it is one object of the present disclosure to provide an inorganic alignment film forming apparatus capable of securing product cost competitiveness by forming an inorganic alignment film on a substrate for an LCOS display with a sputtering means and an ion beam radiation means by applying a mask having oblique slits to the sputtering means and the ion beam radiation means, such that a uniform inorganic alignment film having a high pretilt angle and a large area can be realized.

### Technical Solution

In accordance with one aspect of the present disclosure, provided is an apparatus for forming an inorganic alignment film on a substrate. The apparatus includes a sputtering means, and an ion beam radiation means configured to perform surface treatment of an inorganic alignment film formed by the sputtering means. The sputtering means includes a stage configured to dispose the substrate to form the inorganic alignment film, at least one sputtering gun, and a sputtering mask disposed between the stage and the sputtering gun. The ion beam radiation means includes a stage configured to dispose the substrate, an ion beam emitter configured to generate ions and radiate the same onto the substrate, and an ion beam radiation mask disposed between the stage and the ion beam emitter. A plurality of oblique openings is formed in the sputtering mask and the ion beam radiation mask.

The plurality of oblique openings may be formed in the sputtering mask, wherein an angle formed by an extension direction of each of the openings with respect to a surface of the sputtering mask may be 30° to 60°. The plurality of oblique openings may be formed in the ion beam radiation mask, wherein an angle formed by an extension direction of each of the openings with respect to a surface of the ion beam radiation mask may be 30° to 60°.

The stage may include a jig configured to fix the substrate, and a support configured to support the jig, wherein the support may include a drive motor capable of moving the jig in a horizontal direction.

The sputtering means may include a first sputtering gun having a silicon target formed thereon, and a second sputtering gun having a carbon target formed thereon.

### Advantageous Effects

In an inorganic alignment film forming apparatus according to the present disclosure, while the sputtering process and the ion beam radiation process are integrally performed, a uniform inorganic alignment film is formed by applying a mask having an oblique slit in the sputtering process and the ion beam radiation process. Accordingly, uniformity may be improved, and an inorganic alignment film having a high pretilt angle may be fabricated. Also, a large-area inorganic alignment film may be fabricated. Therefore, the manufacturing cost of products may be lowered and product competitiveness may be enhanced.

### DESCRIPTION OF DRAWINGS

FIG. 1 is a configuration diagram of an inorganic alignment film forming apparatus according to the present disclosure.

FIG. 2 is a detailed configuration diagram of a sputtering means according to the present disclosure.

FIG. 3 is a conceptual diagram illustrating a process of coating silicon atoms and carbon atoms on the surface of a substrate using a sputtering mask according to the present disclosure.

FIG. 4 is a configuration diagram showing the configuration of an ion beam radiation means used in the inorganic alignment film forming apparatus according to the present disclosure.

FIGS. 5 to 6 depict pretilt angles formed by an alignment film formed using the inorganic alignment film forming apparatus according to the present disclosure.

### BEST MODE

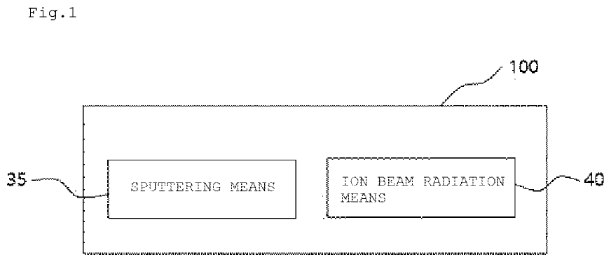

FIG. 1 is a configuration diagram of an inorganic alignment film forming apparatus 100 according to the present disclosure. The inorganic alignment film forming apparatus according to the present disclosure includes a sputtering means 35 and an ion beam radiation means 40. In the present disclosure, an inorganic alignment film is formed on a substrate 22 for an LCOS display. In the present disclosure, the inorganic alignment film is formed on the substrate 22 using one or more inorganic materials selected from among SiO₂, SiC, SiOC and SiON using sputtering means, and the substrate 22 on which the inorganic alignment film is moved to the ion beam radiation means 40 to perform additional surface treatment on the inorganic alignment film.

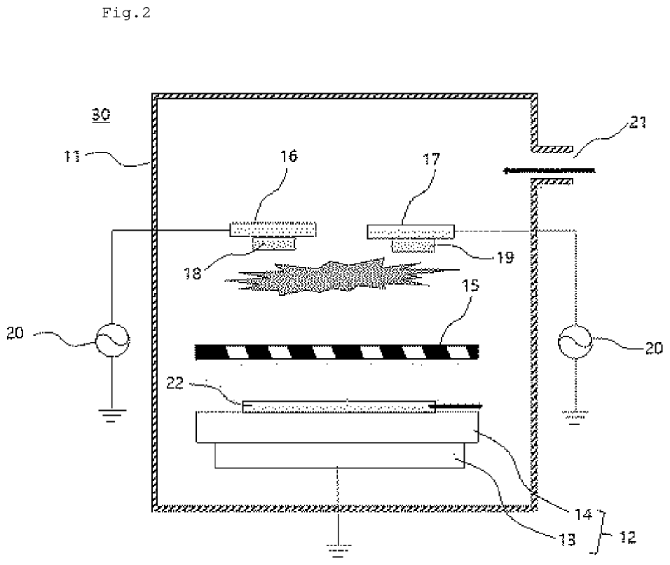

FIG. 2 is a detailed configuration diagram of the sputtering means 35 according to the present disclosure. The sputtering means 35 according to the present disclosure includes a chamber 11, a stage 12 disposed in the chamber 11, sputtering guns 16 and 17, and a sputtering mask 15.

The chamber 11 provides a space in which deposition on the substrate 22 is performed by sputtering. The substrate 22 is mounted on the stage 12 disposed in the chamber 11. The stage 12 includes a jig 14 configured to fix the substrate 22 and a support 13 configured to support the jig 14. The support 13 is provided with a driving means such as a drive motor capable of moving the jig 14 in a horizontal direction. Thus, while deposition is performed in the chamber 11, the substrate 22 may be moved in the horizontal direction with the horizontal position thereof maintained. A ground voltage is applied to the support 13.

At least one sputtering gun 16, 17 is disposed inside the chamber 11. The sputtering gun 16 is disposed above the stage 12 so as to have a predetermined distance from the stage 12. The sputtering guns 16 and 17 are arranged to face in a direction forming a predetermined angle with respect to the surface of the substrate 22 disposed on the stage 12. The angle formed by the direction of the sputtering guns 16 and 17 with the surface of the substrate disposed on the stage 12 may be 30° to 90°. The sputtering guns 16 and 17 may be provided with a driving means capable of adjusting the direction thereof within a range of 30° to 90°. Targets 18 and 19, which are materials for forming an inorganic alignment film, are disposed at ends of the sputtering guns 16 and 17. Each of the targets 18 and 19 may be any one selected from the group consisting of Si, C, Ti, Zr, SiO, and SiC, and may be a mixture of at least two thereof. As a result, an inorganic alignment film selected from among diamond-like carbon (DLC), silicon oxide silicon nitride (SiN), polycrystalline silicon, amorphous silicon, titanium oxide (TiO₂), silicon carbide (SiC), and silicon carbonate (SiOC) may be formed.

The sputtering means 35 according to the present disclosure may include a plurality of sputtering guns 16 and 17, and thus may deposit a plurality of materials at the same time. The sputtering means 35 according to the present disclosure may include two sputtering guns 16 and 17. In this case, a first target 18 used for the first sputtering gun 16 may be a silicon-based material, and a second target 19 used for the sputtering gun 17 may be a carbon-based material. RF power of a radio frequency generated by an RF supply 19 is applied to the first target 18 and the second target 19, respectively.

The RF powers applied to the first target 18 and the second target 19 may be different from each other. The above-described pretilt angle may be adjusted by adjusting the RF power applied to the first target 18 and the RF power applied to the second target 19. For example, the ratio of the RF power applied to the second target 19 to the RF power applied to the first target 18 may be appropriately selected within a range of 1:1 to 5:1. By adjusting the ratio of the RF powers applied to the first target 18 and the second target 19, the composition ratio of the target material in the alignment film formed on the substrate 22 is changed.

When the substrate 22 is disposed on the stage 12, a vacuum condition is created in the chamber 11, and then the process gas is injected through a gas injection port 21. Argon gas (Ar), which is an inert gas, is preferably used as the process gas. Argon gas inside the chamber 11 collides with electrons emitted to the first target 18 and the second target 19 and is excited as argon ions (Ar⁺). The excited argon ions (Ar⁺) collide with the first target 18 and the second target 19. When silicon (Si) is used as the first target 18 and carbon (C) is used as the second target 19, and the argon ions (Ar⁺) collide with the first target 18 and the second target 19, silicon atoms and carbon atoms are released from the first target 18 and the second target 19, respectively. The surface of the substrate 22 is coated with the silicon atoms and carbon atoms emitted from the first target 18 and the second target 19 through the sputtering mask 15. As a result, a vertical alignment layer formed of silicon carbide (SiCₓ) having a vertical alignment force with respect to liquid crystals is formed on the substrate 22.

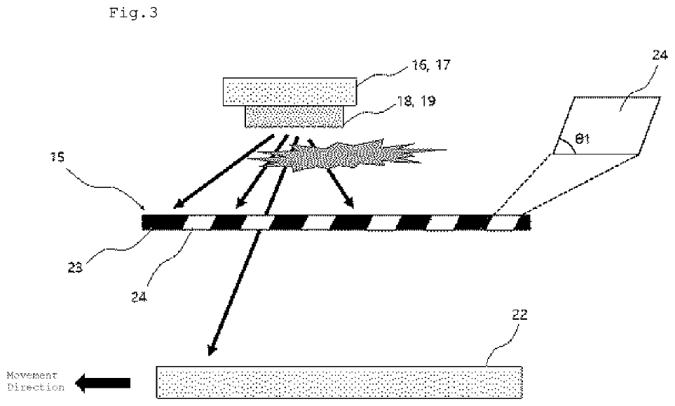

FIG. 3 is a conceptual diagram illustrating a process of coating silicon atoms and carbon atoms on the surface of the substrate 22 using the sputtering mask 15 according to the present disclosure. As shown in FIG. 3, in the sputtering means 35 according to the present disclosure, the sputtering mask 15 is encountered while the atoms emitted from the first target 18 and the second target 19 are directed to the substrate 22.

As shown in FIG. 3, a plurality of oblique slits is formed in the sputtering mask 15. The oblique slits allow the surface of the substrate 22 to be coated with only atoms moving in a predetermined direction, thereby enabling uniform coating. As shown in FIG. 3, the sputtering mask 15 has a structure in which a shielding portion 23 and an opening 24 are alternately repeated to form the oblique slits. Preferably, the distance between the shielding portions 23 or between the openings 24 formed in the sputtering mask 15 is constant. Preferably, the formation angle of each slit, i.e., the angle θ1 formed by the direction of extension of the opening 24 with respect to the surface of the sputtering mask 15 (that is, the angle θ1 formed by the direction of extension of the opening 24 with respect to the substrate 22 disposed on the stage 12)) is preferably 30° to 60°. Preferably, the extension directions of the openings 24 formed in the same sputtering mask 15 are parallel to each other. When the openings 24 are formed at the angle θ1, only the atoms whose traveling direction corresponds to the angle θ1 among the atoms emitted from the first target 18 and the second target 19 and traveling toward the substrate 22 will reach the substrate 22. Thus, a more uniform coating film than in the case where there is no oblique slit may be obtained. While the atoms emitted from the first target 18 and the second target 19 move toward the substrate 22, the support 13 is moved in the horizontal direction. Accordingly, the openings 24 may also continuously move in the horizontal direction, and the entire surface of the substrate 22 may be coated.

As described above, in the sputtering process according to the present disclosure, the above-described pretilt angle may be adjusted high by adjusting the angle at which the atoms emitted from the first target 18 and the second target 19 reach the substrate 22 and adjusting the RF power applied to the first target 18 and the second target 19 so as to control the energy that the atoms have. As a result, an inorganic alignment film having a large area may be formed.

The sputtering mask 15 may be formed of a metal material such as SUS or aluminum, or a material with which slits having a width of several pm to several hundred pm are easily formed, such as ceramic. The thickness of the sputtering mask 15 may be several mm to several hundred mm, for example, 5 mm to 500 mm.

Preferably, the thickness of the inorganic alignment film formed on the substrate 22 by the above-described sputtering means 35 is 100 nm or less.

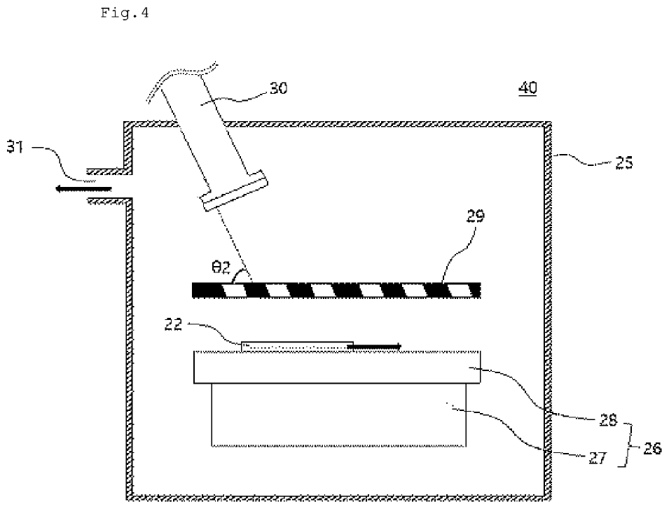

FIG. 4 is a configuration diagram showing the configuration of an ion beam radiation means 40 used in the inorganic alignment film forming apparatus 100 according to the present disclosure. The substrate 22 coated with the inorganic alignment film by the sputtering means 35 is moved into the ion beam radiation means 40 and subjected to surface treatment. As surface treatment proceeds, the surface energy and characteristics of the coating film are changed. The ion beam radiation means 40 includes a chamber 25, a stage 26 disposed in the chamber 25, an ion beam emitter 30, and an ion beam radiation mask 29.

When the substrate 22 is disposed on the stage 26, the gas inside the chamber 25 is discharged through a gas outlet 31 to create a vacuum condition. The ion beam emitter 30 may ionize and emit any one of gases such as hydrogen, helium, neon, nitrogen, argon, krypton, xenon, and oxygen, or may ionize and emit two or more of hydrogen, helium, neon, nitrogen, argon, krypton, xenon, and oxygen. The energy of the ions emitted from the ion beam emitter 30 is preferably adjusted within the range of 0.5 to 3 keV.

A Duoplasmatrontype ion source may be used for the ion beam emitter 30, and preferably covers an area having a diameter of at least 250 mm.

The stage 26 includes a jig 28 for fixing the substrate 25 and a support 27 for supporting the jig 28. The support 27 is provided with a driving means such as a drive motor capable of moving the jig 28 in a horizontal direction. Thus, the substrate 22 fixed to the jig 28 may be kept in a horizontal position and moved in the horizontal direction while the ion beam is radiated into the chamber 25.

The ion beam emitter 30 is disposed inside the chamber 25. The ion beam emitter 30 is disposed above the stage 26 so as to have a predetermined distance from the stage 26. The ion beam emitter 30 is disposed to face in a direction having a predetermined angle with respect to the surface of the substrate 22 disposed on the stage 25. The angle θ2 formed by the direction of the ion beam emitter 30 with the surface of the substrate 22 disposed on the stage 25 may be 30° to 90°. The ion beam emitter 30 may be provided with a driving means capable of adjusting the direction thereof within a range of 30° to 90°.

An ion beam radiation mask 29 having oblique slits is disposed between the ion beam emitter 30 and the stage 25. The material and shape of the ion beam radiation mask 29 and the angle of formation of the openings are substantially the same as those of the sputtering mask 15. That is, a plurality of openings is formed in the ion beam radiation mask 29, and the angle formed by the direction of extension of the openings with respect to the surface of the ion beam radiation mask 29 (that is, the angle formed by the direction of extension of the openings with respect to the surface of the substrate 22) disposed on the stage 25) is preferably 30° to 60°. When the oblique slits are formed in the ion beam radiation mask 29 as described above, only ions traveling toward the substrate 22 at an angle of 30° to 60° with respect to the surface of the substrate 22 disposed on the stage 25 among the ions emitted from the ion beam emitter 30 pass through the openings and reach the substrate 22. The ions traveling in the other directions are blocked by the shielding portion. By allowing only ions traveling in a certain direction to reach the surface of the substrate 22, the surface treatment may be implemented more uniformly. While the surface treatment is performed by the ion beam radiation means 40, the substrate 22 is moved in a horizontal direction. As a result, the entire surface of the substrate 22 is subjected to surface treatment.

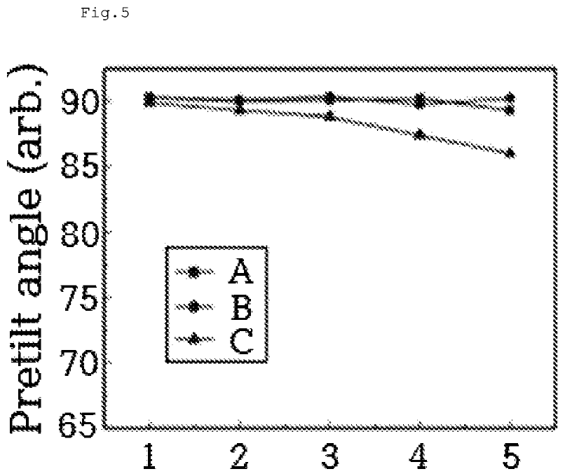

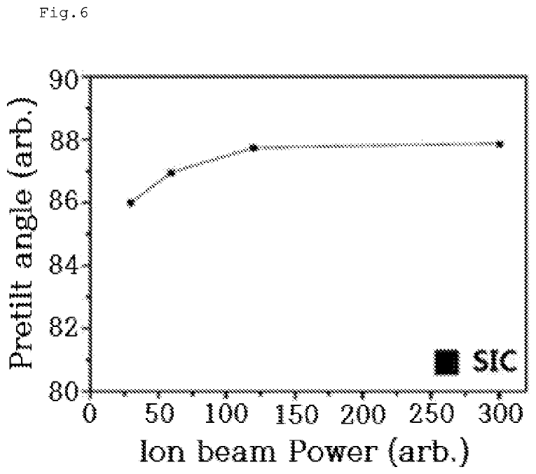

FIGS. 5 to 6 depict pretilt angles formed by an alignment film formed using the inorganic alignment film forming apparatus according to the present disclosure. FIG. 5 depicts a pretilt angle formed when the ratio of the RF power applied to the second target 19 to the RF power applied to the first target 18 is changed within the range of 1:1 to 5:1. In this case, silicon is used as the material of the first target 18 and carbon is used as the material of the second target 19. In the graph of FIG. 5, curves A, B and C represent the cases where the composition ratio of carbon to silicon in the alignment film is 0.5%, 1.0%, and 3.0%, respectively. The composition ratio of carbon to silicon may be obtained by adjusting the angle formed between the direction in which the sputtering guns 16 and 17 face and the surface of the substrate 22 disposed on the stage 12 within the range of 30° to 90°. When the composition ratio of carbon to silicon is adjusted to 0.5%, 1.0%, and 3.0% while a uniform alignment film is formed by the inorganic alignment film forming apparatus 100 according to the present disclosure using the masks 15 and 29 having oblique slits in the sputtering process and the ion beam radiation process as shown in FIG. 4, a high pretilt angle greater than or equal to 86° may be obtained.

FIG. 6 depicts the pretilt angle obtained as a result of surface treatment performed while varying the ion radiation time in the ion beam radiation means 40. In this case, a silicon carbide inorganic alignment film is formed using silicon as a material of the first target 18 and carbon as a material of the second target 19. Change in the pretilt angle is observed over time while radiating an ion beam having an energy of 1.5 keV after adjusting the composition ratio of carbon to silicon to 3.0%. As shown in FIG. 6, when 110 seconds elapses, the change in the pretilt angle decreases, and the pretilt angle is stabilized. As a result, a pretilt angle of 88.7° or more may be obtained. That is, by performing surface treatment by uniformly radiating the ion beam with the ion beam radiation mask 29 applied, the pretilt angle may be further increased.

1. An apparatus for forming an inorganic alignment film on a substrate, comprising:
a sputtering means; and
an ion beam radiation means configured to perform surface treatment of an inorganic alignment film formed by the sputtering means,
wherein the sputtering means comprises:
a stage configured to dispose the substrate to form the inorganic alignment film;
at least one sputtering gun; and
a sputtering mask disposed between the stage and the sputtering gun,
wherein the ion beam radiation means comprises:
a stage configured to dispose the substrate;
an ion beam emitter configured to generate ions and radiate the same onto the substrate; and
an ion beam radiation mask disposed between the stage and the ion beam emitter,
wherein a plurality of oblique openings are formed in the sputtering mask and the ion beam radiation mask.

2. The apparatus of claim 1, wherein the plurality of oblique openings are formed in the sputtering mask,
wherein an angle formed by an extension direction of each of the openings with respect to a surface of the sputtering mask is 30° to 60°.

3. The apparatus of claim 1, wherein the plurality of oblique openings is formed in the ion beam radiation mask,
wherein an angle formed by an extension direction of each of the openings with respect to a surface of the ion beam radiation mask is 30° to 60°.

4. The apparatus of claim 1, wherein the stage comprises:
a jig configured to fix the substrate; and
a support configured to support the jig,
wherein the support comprises a drive motor capable of moving the jig in a horizontal direction.

5. The apparatus of claim 1, wherein the sputtering means comprises:
a first sputtering gun having a silicon target formed thereon; and
a second sputtering gun having a carbon target formed thereon.
